(19) United States
(12) Patent Application Publication
(10) Pub. No.: US 2018/0376089 A1
(43) Pub. Date: Dec. 27, 2018

(54) IMAGE SENSING DEVICE

(71) Applicant: CANON KABUSHIKI KAISHA, Tokyo (JP)

(72) Inventors: Taro Kato, Tokyo (JP); Kazuya Igarashi, Tokyo (JP); Takafumi Miki, Yokohama-shi (JP); Takeshi Ichikawa, Hachioji-shi (JP); Akinari Takagi, Yokosuka-shi (JP)

(21) Appl. No.: 16/116,748

(22) Filed: Aug. 29, 2018

Related U.S. Application Data
(63) Continuation of application No. PCT/JP2017/007894, filed on Feb. 28, 2017.

(30) Foreign Application Priority Data
Mar. 4, 2016 (JP) 2016-042682

(51) Int. Cl. H04N 5/369; G01C 3/08; H01L 27/146

(52) U.S. Cl. CPC H04N 5/36965; G01C 3/085; H01L 27/14645; H01L 27/14621; G06T 7/55; H01L 27/14625; H01L 27/14627; H01L 27/14636; H01L 27/14623

(57) ABSTRACT

An image sensing device includes a first pixel including a first light-shielding member and a second pixel including a second light-shielding member, and the first and second pixels perform phase difference detection. The image sensing device further includes a third pixel including a third light-shielding member, and the third pixel performs image sensing. A third opening in the third light-shielding member is disposed in a center of the third pixel. In a predetermined direction, a length of the third opening is smaller than a length of a first opening in the first light-shielding member and a length of a second opening in the second light-shielding member.

### CROSS-REFERENCE TO RELATED APPLICATIONS

This application is a Continuation of International Patent Application No. PCT/JP2017/007894, filed Feb. 28, 2017, which claims the benefit of Japanese Patent Application No. 2016-042682, filed Mar. 4, 2016, both of which are hereby incorporated by reference herein in their entirety.

### TECHNICAL FIELD

The present invention relates to an image sensing device capable of measuring distances.

### BACKGROUND ART

In recent years, image sensing systems, such as video cameras and electronic still cameras, have been widely used. These cameras include image sensing devices, such as charge-coupled device (CCD) or complementary metal-oxide-semiconductor (CMOS) image sensors. Focus detection pixels having an autofocusing (AF) function for automatic focus adjustment during image capturing have also been in widespread use. Patent Literature (PTL) 1 describes a technique in which, with pixels each including a light shielding member that is partly open, focus detection is performed using a phase difference detection method. From a phase difference between parallax images formed by light rays passed through different regions of a lens pupil (pupil regions), the phase difference detection method determines the defocus value and the distance to the object using the principle of triangulation.

### CITATION LIST

### Patent Literature

PTL 1 Japanese Patent Laid-Open No. 2013-258586

For the purpose of acquiring information for self-sustained travel or movement, vehicle-mounted cameras require image sensing devices that not only maintain high ranging accuracy, but also provide deep focus in which the entire captured image is in focus. For the technique described in PTL 1, however, a device configuration that achieves both high ranging accuracy and deep focus has not been fully studied. Accordingly, the present invention aims to provide an image sensing device that achieves both higher ranging accuracy and deeper focus than those achieved by the technique described in PTL 1.

### SUMMARY OF INVENTION

An image sensing device according to the present invention includes a plurality of pixels two-dimensionally arranged on a substrate. The image sensing device includes a first pixel including a first light-shielding member with a first opening; a second pixel including a second light-shielding member with a second opening, disposed in a first direction with respect to the first pixel, and configured to perform phase difference detection together with the first pixel; and a third pixel including a third light-shielding member with a third opening and configured to perform image sensing. The third opening is disposed in a center of the third pixel. In a second direction orthogonal to the first direction, a length of the third opening is smaller than a length of the first opening and a length of the second opening.

Further features of the present invention will become apparent from the following description of exemplary embodiments with reference to the attached drawings.

### BRIEF DESCRIPTION OF DRAWINGS

FIG. 1 illustrates a first embodiment.

FIGS. 2A to 2E illustrate the first embodiment.

FIG. 3 illustrates the first embodiment.

FIGS. 4A to 4C illustrate modifications of the first embodiment.

FIGS. 5A and 5B illustrate a second embodiment.

FIGS. 6A and 6B illustrate a third embodiment, and FIGS. 6C and 6D illustrate a fourth embodiment.

FIG. 7 illustrates a comparative example.

FIG. 8 illustrates an embodiment of the present invention.

FIG. 9 illustrates the embodiment of the present invention.

FIG. 10 illustrates another embodiment.

FIGS. 11A and 11B illustrate another embodiment.

### DESCRIPTION OF EMBODIMENTS

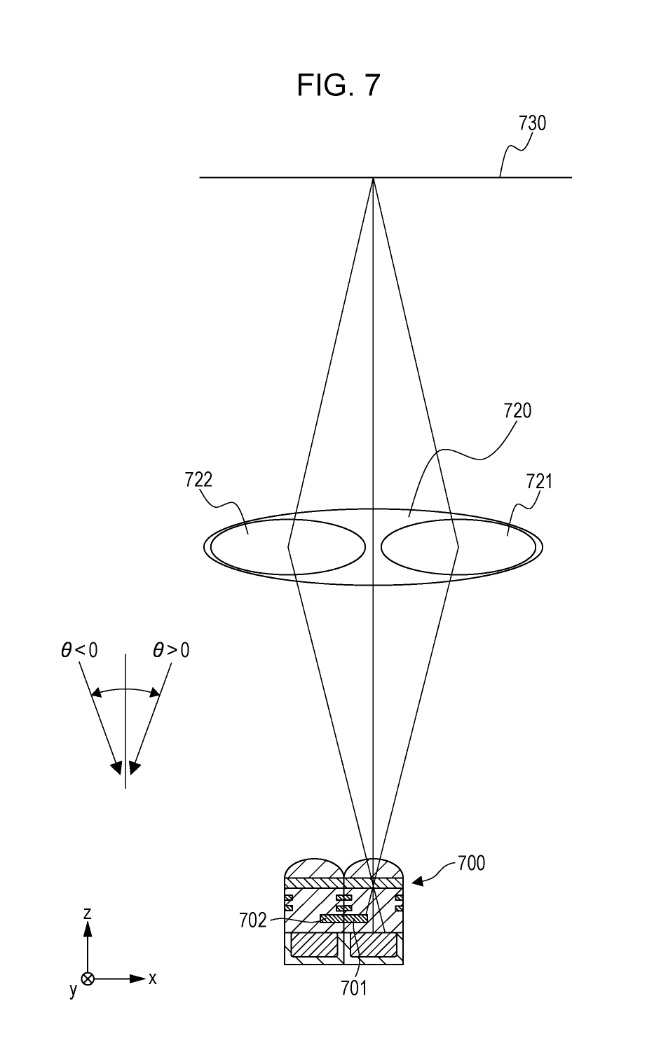

In FIG. 7, reference numeral 700 denotes a ranging pixel, reference numeral 720 denotes an exit pupil of an image sensing lens, and reference numeral 730 denotes an object. In the drawing, the x direction is defined as a pupil dividing direction, along which pupil regions 721 and 722 formed by dividing the exit pupil are arranged. FIG. 7 shows two ranging pixels 700. In the ranging pixel 700 on the right-hand side of FIG. 7, light passed through the pupil region 721 is reflected or absorbed by a light shielding member 701 and only light passed through the pupil region 722 is detected by a photoelectric conversion portion. On the other hand, in the ranging pixel 700 on the left-hand side of FIG. 7, light passed through the pupil region 722 is reflected by a light shielding member 702 and light passed through the pupil region 721 is detected by a photoelectric conversion portion. This makes it possible to acquire two parallax images and perform distance measurement using the principle of triangulation.

Typically, a pixel capable of both ranging and image sensing is configured such that a combined region of the pupil regions 721 and 722, which allow passage of light rays to be incident on the photoelectric conversion portions, is equal to the entire pupil area.

For higher ranging accuracy, however, a larger parallax is required and it is thus necessary to increase the distance between gravity centers of pupil regions corresponding to each parallax.

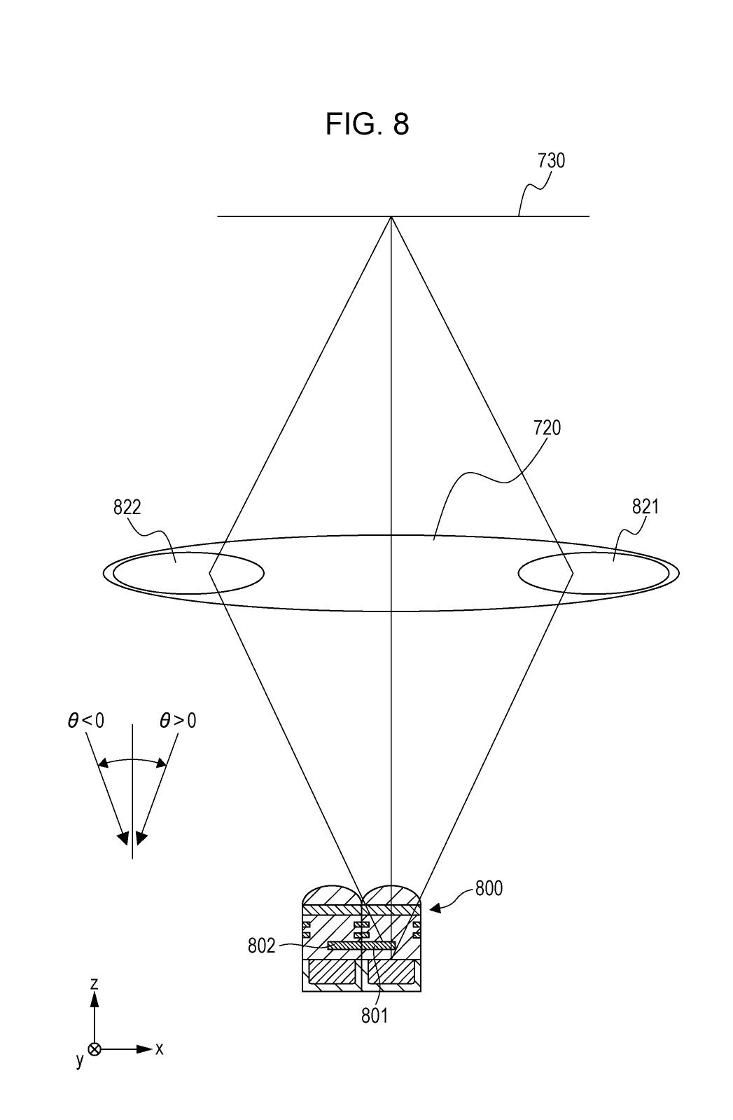

Accordingly, in the present invention, the lens aperture is set to the open state (e.g., open F-number) to increase the baseline length or the distance between gravity centers of the pupil regions 721 and 722. To further increase the distance between the gravity centers of the pupil regions 721 and 722, an opening in the light shielding member of each pixel is reduced in size and positioned at an end portion of the pixel. This is illustrated in FIG. 8. With the lens aperture being in the open state, an opening in the light shielding member 801 and an opening in the light shielding member 802 are each disposed at an end portion of the pixel. Thus, the distance between the gravity centers of a pupil region 821 and a pupil region 822 in FIG. 8 is longer than the distance between the gravity centers of the pupil region 721 and the pupil region 722 in FIG. 7.

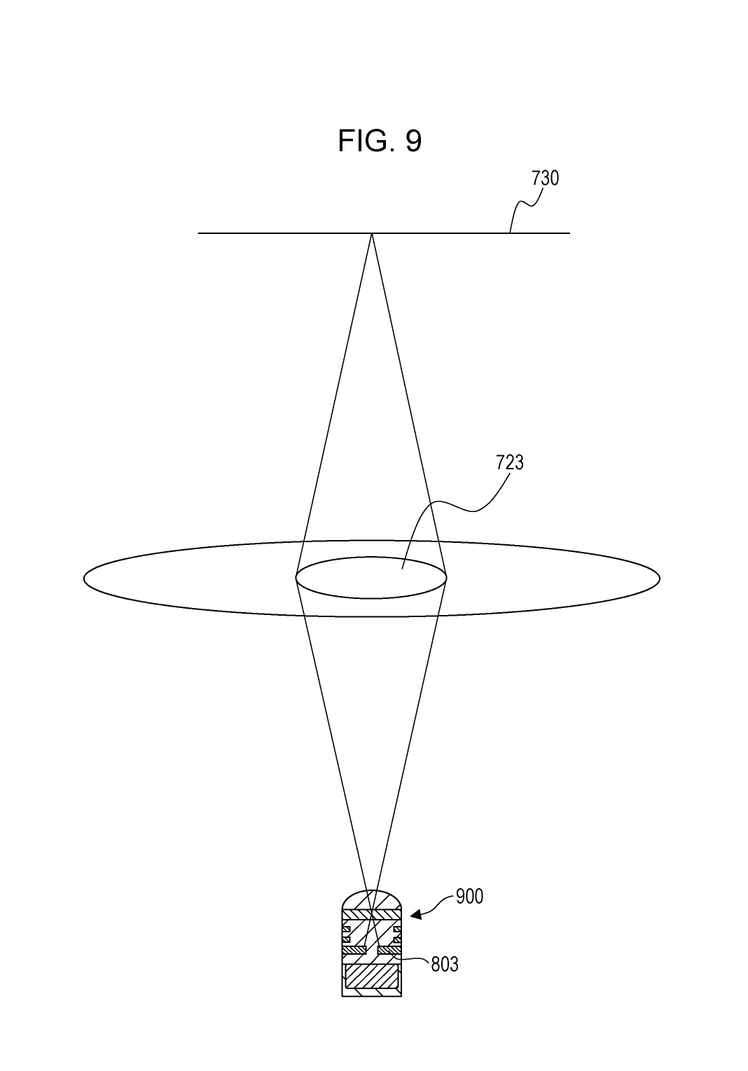

When the lens aperture is set to, for example, the open F-number, the depth of field becomes shallow and this makes it difficult to bring an image into focus over the entire image sensing region. This configuration is not desirable for vehicle-mounted image sensing devices that are required to capture in-focus images of both nearby and distant objects. Accordingly, in the present invention, the size of an opening in each light shielding member is reduced in both the x direction and the y direction, so that a pupil region which allows passage of a light ray used for image sensing is positioned only in the vicinity of the optical axis and reduced in size. This is illustrated in FIG. 9. As illustrated, an opening in a light shielding member 803 of an image sensing pixel 900 occupies a small area and is disposed in the center of the image sensing pixel 900. With this configuration, a pupil region 723 is positioned only in the vicinity of the optical axis. An image sensing device can thus be provided, in which even when the lens aperture is set to, for example, the open F-number, the depth of field does not become shallow. That is, it is possible to provide an image sensing device that can achieve both high ranging accuracy and deep focus. Each embodiment will now be described.

### First Embodiment

### General Configuration of Image Sensing Device

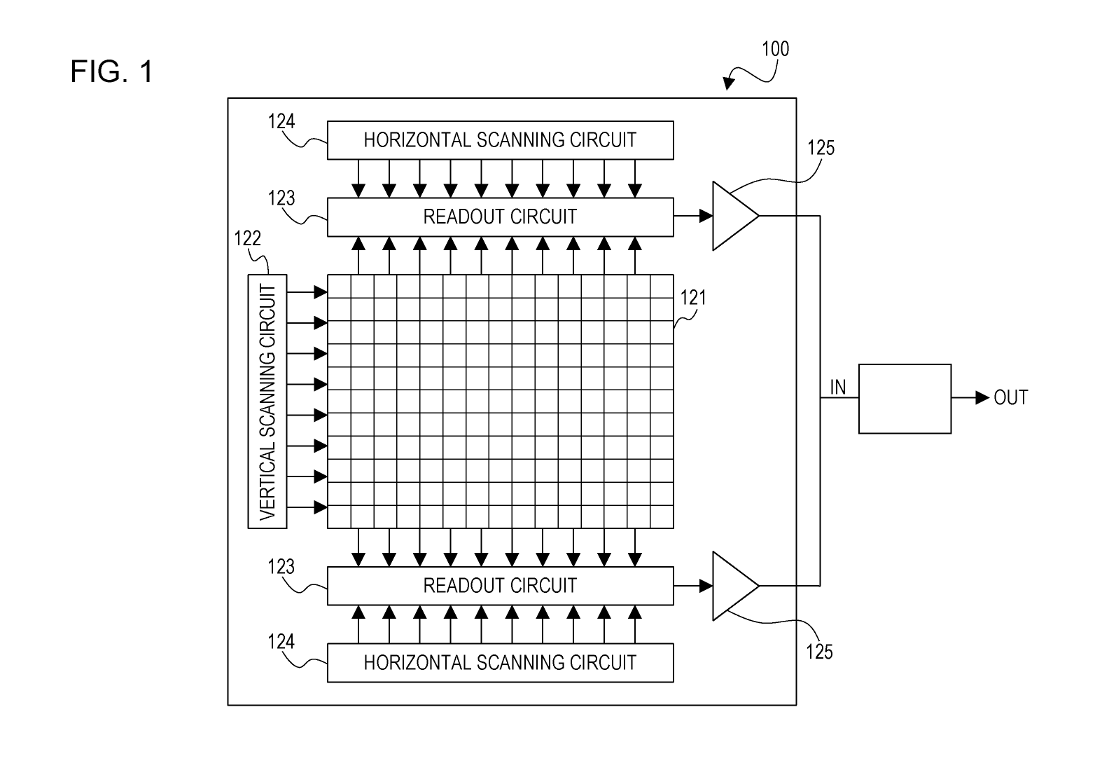

FIG. 1 is a block diagram of an image sensing device 100 including ranging pixels and image sensing pixels according to a first embodiment of the present invention. The image sensing device 100 includes a pixel region 121, a vertical scanning circuit 122, two readout circuits 123, two horizontal scanning circuits 124, and two output amplifiers 125. A region outside the pixel region 121 is a peripheral circuit region. The pixel region 121 includes many ranging pixels and image sensing pixels two-dimensionally arranged. The peripheral circuit region includes the readout circuits 123, such as column amplifiers, correlated double sampling (CDS) circuits, and adding circuits. The readout circuits 123 each amplify and add up signals that are read, through a vertical signal line, from pixels in a row selected by the vertical scanning circuit 122. The horizontal scanning circuits 124 each generate signals for sequentially reading signals based on pixel signals from the corresponding readout circuit 123. The output amplifiers 125 each amplify and output signals in a column selected by the corresponding horizontal scanning circuit 124. Although a configuration that uses electrons as signal charge is described as an example, positive holes may be used as signal charge.

### Device Configuration of Each Pixel

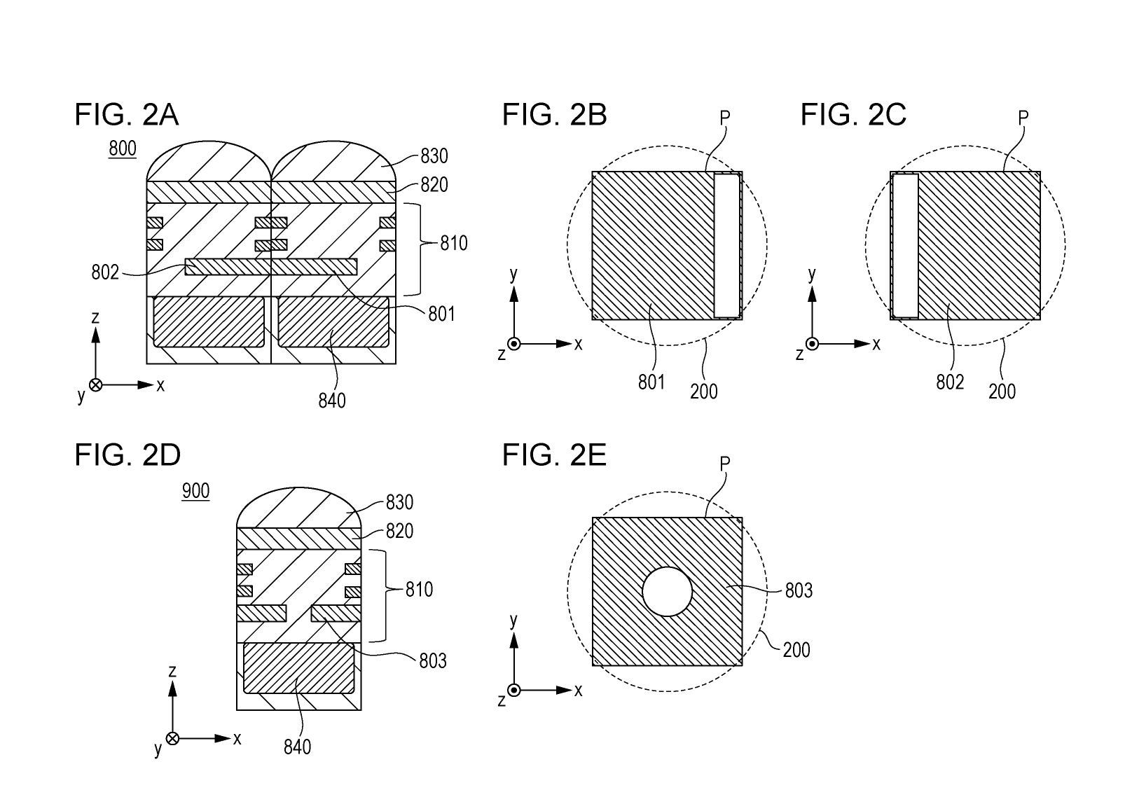

FIGS. 2A to 2C illustrate ranging pixels 800 and FIGS. 2D and 2E illustrate the image sensing pixel 900. In the present embodiment, where electrons are used as signal charge, the first conductivity type is n-type and the second conductivity type is p-type. Alternatively, holes may be used as signal charge. When holes are used as signal charge, the conductivity type of each semiconductor region is the reverse of that when electrons are used as signal charge.

FIG. 2A is a cross-sectional view of the ranging pixels 800, and FIG. 2B is a plan view of one of the ranging pixels 800. Some of the components shown in the cross-sectional view are omitted in the plan view, and the cross-sectional view is partly presented more abstractly than the plan view. As illustrated in FIG. 2A, introducing impurities into the p-type semiconductor region in the semiconductor substrate produces a photoelectric conversion portion 840 formed by the n-type semiconductor region. A wiring structure 810 is formed on the semiconductor substrate. The wiring structure 810 is internally provided with the light shielding member 801 (first light-shielding member) and the light shielding member 802 (second light-shielding member). A color filter 820 and a microlens 830 are disposed on the wiring structure 810.

The wiring structure 810 includes a plurality of insulating films and a plurality of conductive lines. Layers forming the insulating films are made of, for example, silicon oxide, borophosphosilicate glass (BPSG), phosphosilicate glass (PSG), borosilicate glass (BSG), silicon nitride, or silicon carbide. A conductive material, such as copper, aluminum, tungsten, tantalum, titanium, or polysilicon, is used to form the conductive lines.

The light shielding members 801 and 802 may be made of the same material as the conductive line portion, and the conductive line portion and the light shielding members may be produced in the same process. Although a light shielding member is formed as part of the lowermost layer of multiple wiring layers in FIG. 2A, it may be formed in any part of the wiring structure 810. For example, when the wiring structure 810 includes a waveguide to improve light collecting performance, the light shielding member may be formed on the waveguide. The light shielding member may be formed as part of the uppermost wiring layer, or may be formed on the uppermost wiring layer.

The color filter 820 is a filter that transmits light of red (R), green (G), and blue (B) or light of cyan (C), magenta (M), and yellow (Y). The color filter 820 may be a white filter or infrared (IR) filter that transmits light of RGB or CMY wavelengths. In particular, since image sensing does not involve identifying colors, a white filter may be used for a ranging pixel to achieve improved sensitivity. If using a plurality of types of color filters 820 creates a level difference between them, a planarizing layer may be provided on the color filters 820.

The microlens 830 is formed using, for example, resin. The pixel including the light shielding member 801, the pixel including the light shielding member 802, and the pixel including the light shielding member 803 have different microlenses thereon. When the optimum microlens shape for ranging differs from that for image sensing, the microlens shape for ranging pixels may be made different from that for image sensing pixels.

FIG. 2B is a plan view of the ranging pixel 800 disposed on the right-hand side in FIG. 2A, and FIG. 2C is a plan view of the ranging pixel 800 disposed on the left-hand side in FIG. 2A. As illustrated in FIGS. 2B and 2C, the opening in the light shielding member 801 is disposed at an end portion of a pixel P (first pixel), and the opening in the light shielding member 802 is disposed at an end portion of another pixel P (second pixel). The opening in the light shielding member 801 and the opening in the light shielding member 802 are disposed at opposite end portions, and the x direction (first direction) is a phase difference detection direction. Distance measurement is performed on the basis of a signal obtained from incident light passed through the opening in the light shielding member 801 and a signal obtained from incident light passed through the opening in the light shielding member 802. For example, a region provided with one microlens may be defined as one pixel.

FIG. 2D is a cross-sectional view of the image sensing pixel 900 and FIG. 2E is a plan view of the image sensing pixel 900. The light shielding member 803 is made of the same material as the light shielding members 801 and 802.

As illustrated in FIG. 2E, the opening in the light shielding member 803 (third light-shielding member) is disposed in the center of a pixel P (third pixel). A comparison between FIGS. 2B and 2C and FIG. 2E shows that in the y direction (second direction) orthogonal to the x direction, the length of the opening in the light shielding member 803 is smaller than the length of the light shielding member 801 and the length of the light shielding member 802. For example, in the y direction, the length of the opening in the light shielding member 803 is less than or equal to ⅓ of the length of the opening in the light shielding member 801 and the length of the opening in the light shielding member 802. Also, for example, in the x direction, the width of the opening in the light shielding member 803 is less than or equal to ⅓ of the width of the pixel P. Also, for example, the area of the opening in the light shielding member 803 is smaller than the sum of the area of the opening in the light shielding member 801 and the area of the opening in the light shielding member 802. With this configuration, a pupil region can be positioned only in the vicinity of the optical axis and reduced in size.

In the x direction, the width of the opening in the light shielding member 801 and the width of the opening in the light shielding member 802 are smaller than the width of the opening in the light shielding member 803. The opening in the light shielding member 801 and the opening in the light shielding member 802 are each disposed on one side of the pixel. It is thus possible to increase the distance between the gravity centers of a pupil region for the pixel including the light shielding member 801 and a pupil region for the pixel including the light shielding member 802. For example, in the x direction, the width of the opening in the light shielding member 801 and the width of the opening in the light shielding member 802 are less than or equal to ¼ of the width of the pixel P.

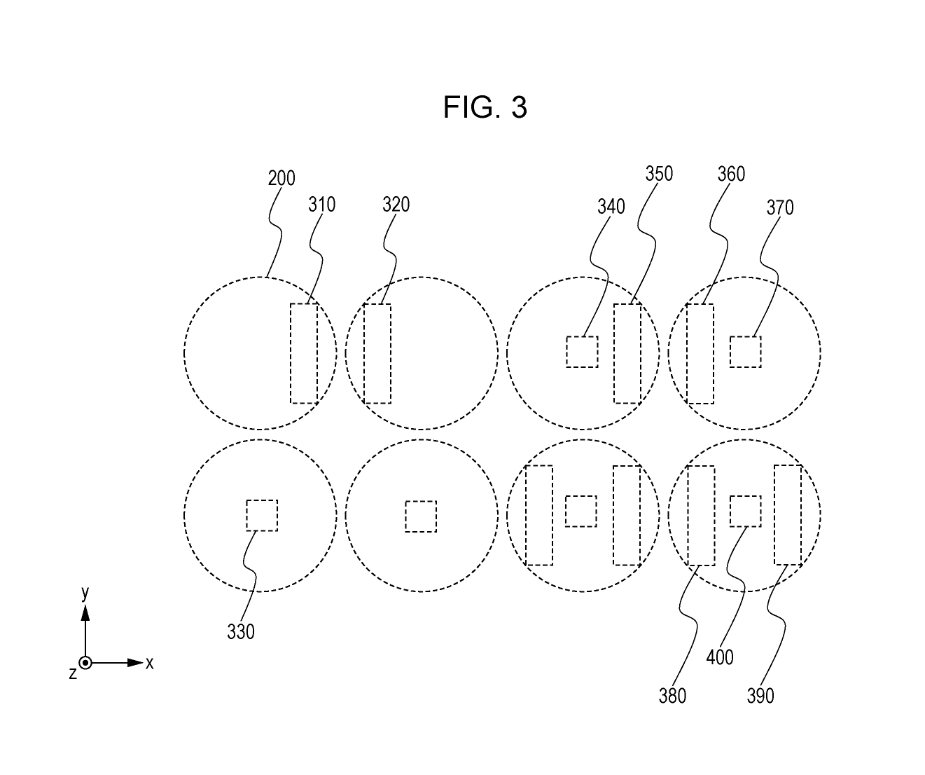

In FIGS. 2B, 2C, and 2E, reference numeral 200 denotes the outer rim of the microlens 830. A relation between the microlens and the opening in each light shielding member will now be described using FIG. 3.

FIG. 3 schematically illustrates microlenses arranged in the pixel region 121. In the x direction (first direction), a plurality of microlenses are one-dimensionally arranged. This is referred to as a microlens group. At the same time, along the y direction (second direction) orthogonal to the first direction, a plurality of microlens groups are arranged, and thereby a plurality of microlenses are two-dimensionally arranged. This is referred to as a microlens array. The plurality of microlenses each have the outer rim 200 and a center. Also, the plurality of microlenses each have a first end portion and a second end portion disposed opposite the first end portion in the x direction, with the center of the microlens interposed therebetween. A plurality of openings are arranged to overlap a plurality of microlenses in plan view. For example, in FIG. 3, reference numerals 320, 360, and 380 each denote a schematic representation of the opening in the first light-shielding member, and the opening is disposed to overlap the first end portion of the microlens. Reference numerals 310, 350, and 390 each denote a schematic representation of the opening in the second light-shielding member, and the opening is disposed to overlap the second end portion of the microlens. Reference numerals 330, 340, 370, and 400 each denote a schematic representation of the opening in the third light-shielding member, and the opening is disposed to overlap the center of the microlens. Thus, at least one of the opening in the first light-shielding member, the opening in the second light-shielding member, and the opening in the third light-shielding member is disposed to correspond to an appropriate position in each

With the configuration described above, it is possible to provide an image sensing device that can achieve both high ranging accuracy and deep focus.

### Modifications of First Embodiment

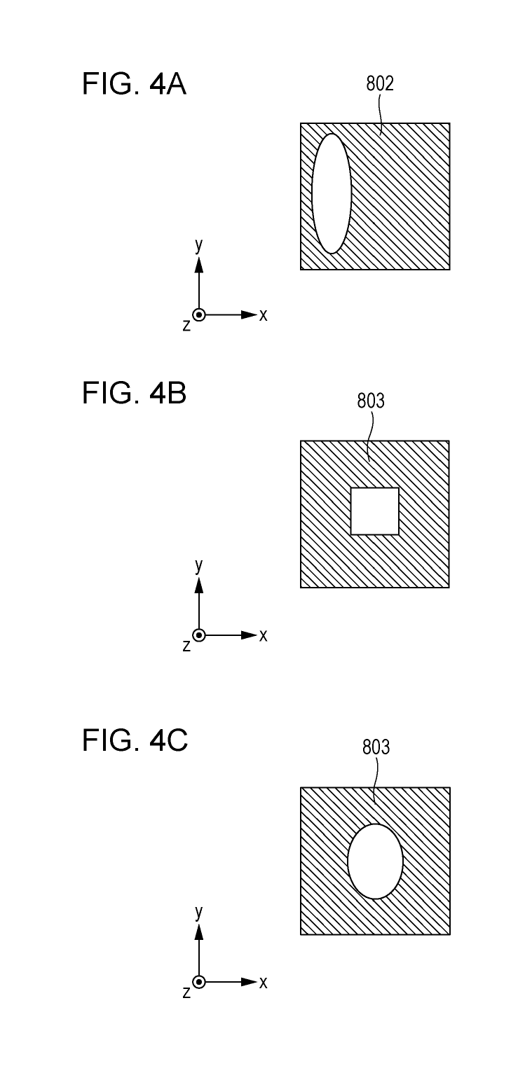

FIGS. 4A to 4C illustrate modifications of the present embodiment. FIG. 4A is a plan view of the ranging pixel 800. As illustrated, the opening in the light shielding member 802 may be oval instead of rectangular. FIGS. 4B and 4C are each a plan view of the image sensing pixel 900. As illustrated, the opening in the light shielding member 803 may be either rectangular or oval. The opening in the light shielding member 803 may have another polygonal shape, such as a pentagonal or octagonal shape, instead of a quadrangular shape.

### Second Embodiment

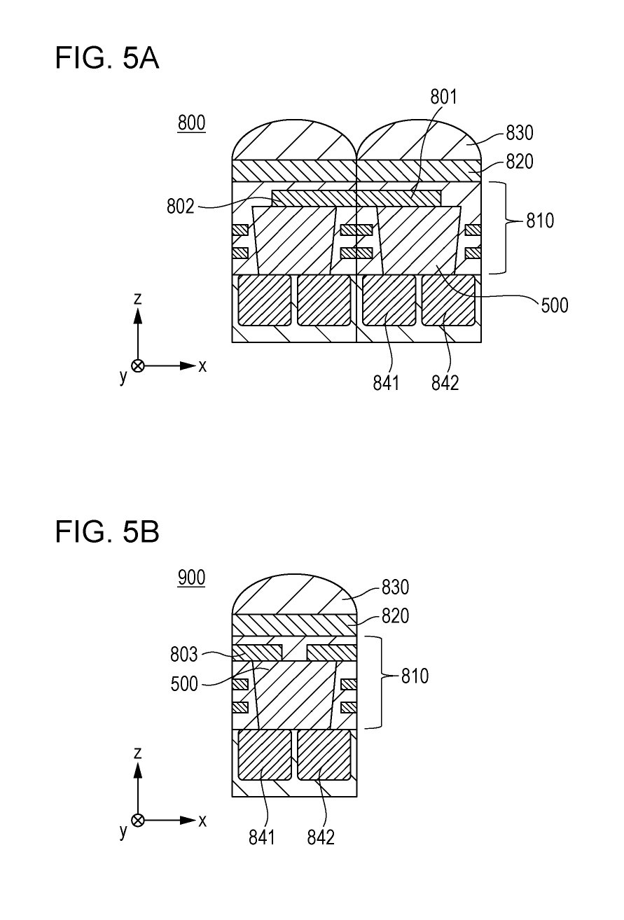

FIG. 5A is a cross-sectional view of the ranging pixels 800, and FIG. 5B is a cross-sectional view of the image sensing pixel 900. In the present embodiment, the wiring structure 810 is internally provided with a waveguide 500. The waveguide 500 is made of a material with a refractive index higher than the refractive index of insulating layers of the wiring structure 810. The light shielding members 801 and 802 are each disposed above the waveguide 500, not in the first wiring layer in a pixel region. Here, the pixel region refers to a region with photoelectric conversion portions, transfer transistors, and amplification transistors. A peripheral region refers to a region disposed around and outside the pixel region. The light shielding members 801 and 802 in the pixel region may be produced in the same process as that of forming the wiring layer in the peripheral region. In the present embodiment, each pixel includes a plurality of photoelectric conversion portions, that is, a photoelectric conversion portion 841 and a photoelectric conversion portion 842. For example, in the ranging pixel 800 disposed on the right-hand side in FIG. 5A, when a signal is read from the photoelectric conversion portion 842 alone, the resulting ranging accuracy is higher than that achieved when signals are read from both the photoelectric conversion portions 841 and 842. As illustrated in FIG. 5A, in the x direction (first direction), the width of the opening in the light shielding member 801 is smaller than the width of the photoelectric conversion portion 841 and the width of the photoelectric conversion portion 842. Similarly, the width of the opening in the light shielding member 802 is smaller than the width of the photoelectric conversion portion 841 and the width of the photoelectric conversion portion 842. Additionally, as illustrated in FIG. 5B, the width of the opening in the light shielding member 803 is also smaller than the width of the photoelectric conversion portion 841 and the width of the photoelectric conversion portion 842.

### Third Embodiment

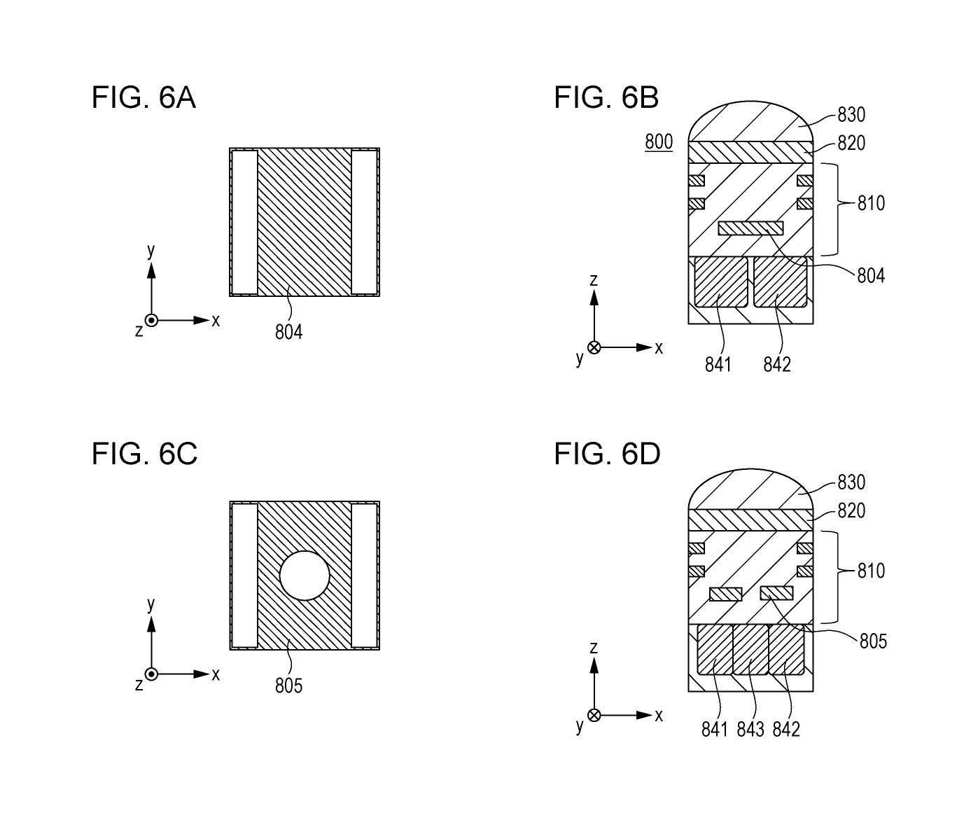

FIGS. 6A and 6B are a plan view and a cross-sectional view, respectively, of the ranging pixel 800. In the ranging pixels 800 illustrated in FIGS. 2A to 2C and FIG. 4A, the light shielding member of each pixel has one opening. In the present embodiment, however, a light shielding member 804 has two openings, which correspond to the photoelectric conversion portions 841 and 842. As illustrated in FIG. 6B, in the x direction (first direction), the width of the two openings in the light shielding member 804 is smaller than the width of the photoelectric conversion portions 841 and 842. At for image sensing pixels, the image sensing pixel 900 described with reference to FIGS. 2D and 2E may be used as the image sensing pixel of the present embodiment. Alternatively, the image sensing pixel 900 illustrated in FIGS. 2D and 2E may include two photoelectric conversion portions, and this pixel with two photoelectric conversion portions may be used as the image sensing pixel of the present embodiment.

### Fourth Embodiment

FIGS. 6C and 6D are a plan view and a cross-sectional view, respectively, of a pixel with both a ranging function and an image sensing function. A light shielding member 805 has one opening in the center thereof for use in image sensing. The light shielding member 805 also has two openings at both end portions thereof. The photoelectric conversion portions 841, 842, and 843 are arranged to correspond to a total of three openings. In FIG. 6D, in the x direction (first direction), the width of the three openings in the light shielding member 805 is smaller than the width of the photoelectric conversion portions 841 to 843.

### Other Embodiments

Although a front-illuminated image sensing device has been described as an example in the embodiments described above, the present invention is also applicable to back-illuminated image sensing devices. Although a photoelectric conversion portion formed by a semiconductor region is used in the embodiments described above, a photoelectric conversion layer containing an organic compound may be used as the photoelectric conversion portion. In this case, the photoelectric conversion layer may be sandwiched between a pixel electrode and a counter electrode, and the light shielding member described above may be disposed on the counter electrode formed by a transparent electrode.

### Embodiment of Image Sensing System

The present embodiment is an embodiment of an image sensing system using an image sensing device including ranging pixels and image sensing pixels according to any of the embodiments described above. Examples of the image sensing system include a vehicle-mounted camera.

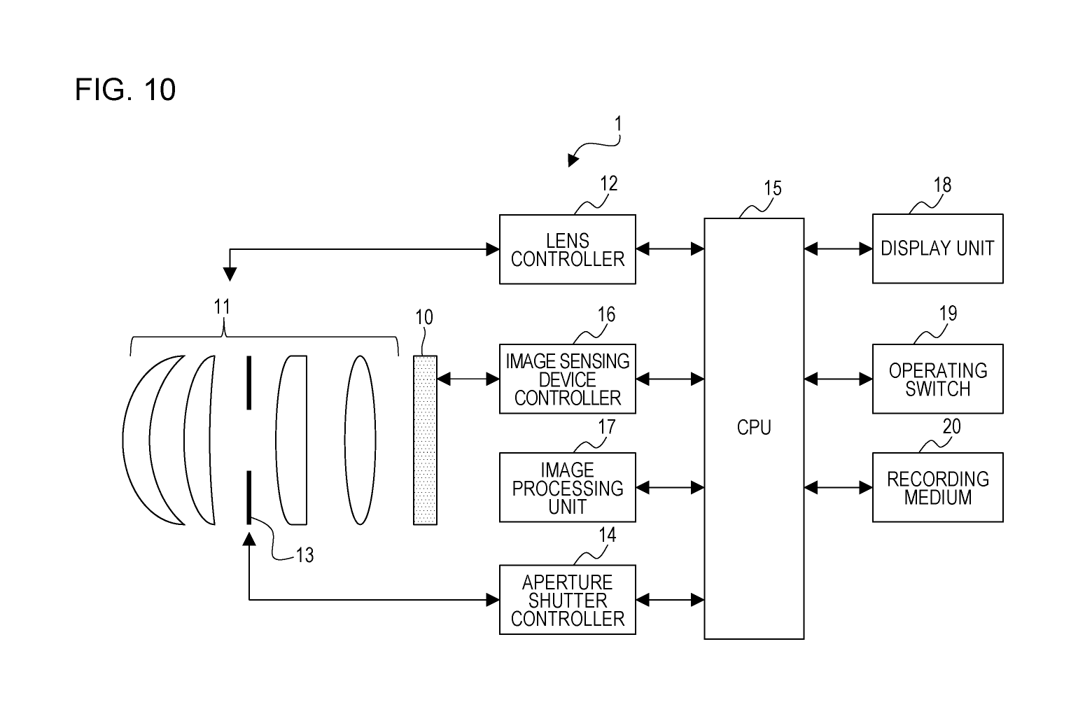

FIG. 10 illustrates a configuration of an image sensing system 1. The image sensing system 1 is equipped with an image sensing lens which is an image sensing optical system 11. A lens controller 12 controls the focus position of the image sensing optical system 11. An aperture member 13 is connected to an aperture shutter controller 14, which adjusts the amount of light by varying the opening size of the aperture. In an image space of the image sensing optical system 11, an image sensing surface of an image sensing device 10 is disposed to acquire an object image formed by the image sensing optical system 11. A central processing unit (CPU) 15 is a controller that controls various operations of the camera. The CPU 15 includes a computing unit, a read-only memory (ROM), a random-access memory (RAM), an analog-to-digital (A/D) converter, a digital-to-analog (D/A) converter, and a communication interface circuit. The CPU 15 controls the operation of each part of the camera in accordance with a computer-program stored in the ROM, and executes a series of image capturing operations which involve measurement of distance to the object, autofocusing (AF) operation including detection of the focus state of an image capturing optical system (focus detection), image sensing, image processing, and recording. The CPU 15 corresponds to signal processing means. An image sensing device controller 16 controls the operation of the image sensing device 10 and transmits a pixel signal (image sensing signal) output from the image sensing device 10 to the CPU 15. An image processing unit 17 performs image processing, such as γ conversion and color interpolation, on the image sensing signal to generate an image signal. The image signal is output to a display unit 18, such as a liquid crystal display (LCD). With an operating switch 19, the CPU 15 is operated and the captured image is recorded in a removable recording medium 20.

### Embodiment of Vehicle-Mounted Image Sensing System

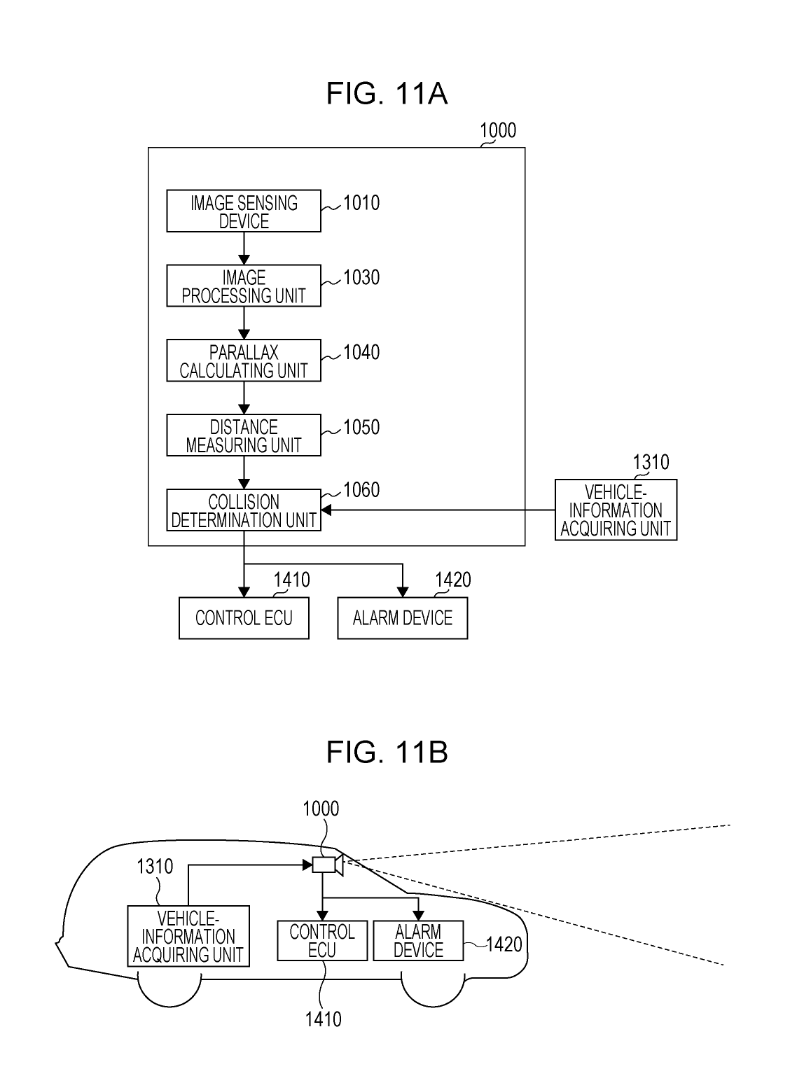

FIGS. 11A and 11B illustrate an image sensing system related to a vehicle-mounted camera. An image sensing system 1000 is an image sensing system that includes the ranging pixels and image sensing pixels according to the present invention. The image sensing system 1000 includes an image processing unit 1030 that performs image processing on a plurality of pieces of image data acquired by an image sensing device 1010, and a parallax calculating unit 1040 that calculates a parallax (i.e., phase difference between parallax images) from the plurality of pieces of image data acquired by the image sensing device 1010. The image sensing system 1000 also includes a distance measuring unit 1050 that calculates a distance to an object on the basis of the calculated parallax, and a collision determination unit 1060 that determines the possibility of collision on the basis of the calculated distance. The parallax calculating unit 1040 and the distance measuring unit 1050 are examples of distance information acquiring means for acquiring distance information about a distance to the object. That is, the distance information is information related to parallax, defocus value, distance to the object, and the like. The collision determination unit 1060 may determine the possibility of collision using any of the distance information described above. The distance information acquiring means may be implemented by specifically-designed hardware or a software module. The distance information acquiring means may be implemented by a field programmable gate array (FPGA), an application-specific integrated circuit (ASIC), or a combination of both.

The image sensing system 1000 is connected to a vehicle information acquiring device 1310, by which vehicle information, such as vehicle speed, yaw rate, and rudder angle, can be acquired. The image sensing system 1000 is also connected to a control ECU 1410 which is a control device that outputs a control signal for generating a braking force to the vehicle on the basis of the determination made by the collision determination unit 1060. The image sensing system 1000 is also connected to an alarm device 1420 that gives an alarm to the vehicle driver on the basis of the determination made by the collision determination unit 1060. For example, if the collision determination unit 1060 determines that a collision is highly likely, the control ECU 1410 performs vehicle control which involves, for example, actuating the brake, releasing the accelerator, or suppressing the engine output, to avoid the collision or reduce damage. The alarm device 1420 gives an alarm to the user, for example, by sounding an audio alarm, displaying alarm information on the screen of a car navigation system, or vibrating the seatbelt or steering wheel.

In the present embodiment, the image sensing system 1000 senses an image of the surroundings of the vehicle, such as the front or rear of the vehicle. FIG. 11B illustrates the image sensing system 1000 which is in operation for sensing an image of the front of the vehicle. Although a control operation performed to avoid a collision with other vehicles has been described, the same configuration as above can be used to control automated driving which is carried out in such a manner as to follow other vehicles, and to control automated driving which is carried out in such a manner as to avoid deviation from the driving lane. The image sensing system described above is applicable not only to vehicles, such as those having the image sensing system mounted thereon, but also to moving bodies (moving apparatuses), such as ships, aircrafts, and industrial robots. The image sensing system is applicable not only to moving bodies, but is also widely applicable to devices using object recognition techniques, such as intelligent transport systems (ITSs).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. An image sensing device including a plurality of pixels two-dimensionally arranged on a substrate, the image sensing device comprising:
a first pixel including a first light-shielding member with a first opening;
a second pixel including a second light-shielding member with a second opening, disposed in a first direction with respect to the first pixel, and configured to perform phase difference detection together with the first pixel; and
a third pixel including a third light-shielding member with a third opening and configured to perform image sensing,
wherein the third opening is disposed in a center of the third pixel; and
in a second direction orthogonal to the first direction, a length of the third opening is smaller than a length of the first opening and a length of the second opening.

2. The image sensing device according to claim 1, wherein in the first direction, a width of the first opening and a width of the second opening are smaller than a width of the third opening.

3. The image sensing device according to claim 1, wherein in the first direction, a width of the third opening is smaller than a distance between the first opening and the second opening.

4. The image sensing device according to claim 1, wherein a microlens on the first pixel differs from a microlens on the second pixel.

5. The image sensing device according to claim 1, wherein an area of the third opening is smaller than a sum of an area of the first opening and an area of the second opening.

6. The image sensing device according to claim 1, wherein the first pixel, the second pixel, and the third pixel each include a plurality of photoelectric conversion portions.

7. The image sensing device according to claim 6, wherein in the first direction, a width of the first opening and a width of the second opening are smaller than a width of the photoelectric conversion portions.

8. An image sensing device comprising:
a microlens array including a plurality of microlens groups each including a plurality of microlenses arranged along a first direction, the microlens groups being arranged in a second direction orthogonal to the first direction;
a plurality of photoelectric conversion portions arranged in such a manner that each of the plurality of microlenses is overlapped by at least one of the plurality of photoelectric conversion portions in plan view; and
a plurality of light shielding members each disposed between one of the plurality of microlenses and the at least one of the plurality of photoelectric conversion portions,
wherein the microlenses each have a first end portion and a second end portion disposed opposite the first end portion in the first direction, with a center of the microlens interposed therebetween;
the light shielding members each have a plurality of openings including a first opening disposed to overlap the first end portion, a second opening disposed to overlap the second end portion, and a third opening disposed to overlap the center of the microlens; and
in the second direction, a length of the third opening is smaller than a length of the first opening and a length of the second opening.

9. A moving body comprising:
the image sensing device according to claim 1;
distance information acquiring means for acquiring distance information from parallax images based on signals from the image sensing device, the distance information being information about a distance to an object; and
control means for controlling the moving body on the basis of the distance information.
